(19) United States
(12) Patent Application Publication
(10) Pub. No.: US 2024/0099063 A1
(43) Pub. Date: Mar. 21, 2024

(54) DISPLAY PANEL AND DISPLAY DEVICE

(71) Applicant: LG DISPLAY CO., LTD., Seoul (KR)

(72) Inventors: Dohyung LEE, Gyeonggi-do (KR); JuHeyuck BAECK, Seoul (KR); Jiyong NOH, Gyeonggi-do (KR); HongRak CHOI, Seoul (KR); ChanYong JEONG, Gyeonggi-do (KR)

(73) Assignee: LG DISPLAY CO., LTD., SEOUL (KR)

(21) Appl. No.: 18/241,283

(22) Filed: Sep. 1, 2023

(30) Foreign Application Priority Data
Sep. 20, 2022 (KR) 10-2022-0118452

(51) Int. Cl. H10K 59/121; H10K 59/126; H10K 71/00

(52) U.S. Cl. CPC H10K 59/1213; H10K 59/1216; H10K 59/126; H10K 71/861; H10K 2102/351

(57) ABSTRACT

A display panel and a display device both include a first active layer disposed on a substrate and including a channel area, a first area positioned on a first side of the channel area, and a second area positioned on a second side of the channel area, a first conductor on the first area, a second conductor on the second area, and a first auxiliary electrode on the first conductor, wherein an area where the first auxiliary electrode is disposed includes a repair area, thereby facilitating to repair a subpixel while mitigating or minimizing instantaneous ghosting on panel.

### CROSS-REFERENCE TO RELATED APPLICATION

This application claims the priority of Korean Patent Application No. 10-2022-0118452, filed on Sep. 20, 2022, which is hereby incorporated by reference in its entirety.

### BACKGROUND

### Field of the Disclosure

The present disclosure relates to a display panel and a display device, and more particularly, for example, without limitation, to a display panel comprising a repair area and a display device comprising a repair area.

### Description of the Background

Transistors are widely used as switching devices or driving devices in the field of electronic devices.

In particular, thin film transistors are widely used as driving or switching devices in display devices such as liquid crystal display devices or organic light-emitting display devices because they may be manufactured on glass or plastic substrates. Display devices including such thin film transistors are prone to image blotches the cause of which is difficult to figure out.

The description provided in the description of the related art section should not be assumed to be prior art merely because it is mentioned in or associated with the description of the related art section. The description of the related art section may include information that describes one or more aspects of the subject technology, and the description in this section does not limit the disclosure

### SUMMARY

Accordingly, the present disclosure is directed to a display panel and a display device that substantially obviate one or more of problems due to limitations and disadvantages described above.

More specifically, the present disclosure is to provide a display panel and a display device capable of preventing instantaneous ghosting on panel.

In addition, the present disclosure is to provide a display panel and a display device capable of preventing instantaneous ghosting on panel while facilitating a subpixel repair process through cutting the active layer.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display panel includes a first active layer disposed on a substrate and including a channel area, a first area positioned on a first side of the channel area, and a second area positioned on a second side of the channel area, a first conductor on the first area, a second conductor on the second area, and a first auxiliary electrode on the first conductor, wherein an area where the first auxiliary electrode is disposed includes a repair area, thereby facilitating to repair a subpixel while mitigating instantaneous ghosting on panel.

Furthermore, the display panel may further comprise a second active layer disposed on the same layer as the first active layer and being spaced apart from the first active layer.

Furthermore, the display panel may further comprise a first additional auxiliary electrode disposed on the first active layer, and a second additional auxiliary electrode and a third additional auxiliary electrode spaced apart from each other and disposed on the second active layer.

Furthermore, the display panel may further comprise a second auxiliary electrode disposed on the second conductor.

Furthermore, each of the first auxiliary electrode and the second auxiliary electrode may include one type of metal or an alloy in which two or more types of metal components are mixed, and each of the first conductor and the second conductor may include a transparent conductive oxide.

Furthermore, each of the first and second auxiliary electrodes may be formed of MoTi, and each of the first and second conductors may be formed of indium zinc oxide (IZO).

Furthermore, a content ratio of indium (In) to zinc (Zn) included in each of the first and second conductors may be 5:5 to 7:3.

Furthermore, thicknesses of each of the first and second auxiliary electrodes may be larger than or equal to thicknesses of each of the first and second conductors.

Furthermore, each of the first and second auxiliary electrodes may have a thickness of 100 Å to 200 Å, and each of the first and second conductors may have a thickness of 70 Å to 100 Å.

Furthermore, the first area overlapping with the first auxiliary electrode may be cut during a repair process of the display panel.

Furthermore, the display panel may further comprise a first electrode on the first auxiliary electrode; a second electrode on the second auxiliary electrode; a gate insulation film on the channel area; and a third electrode disposed on the gate insulation film.

Furthermore, the gate insulation film may include a first gate insulation film portion disposed to cover a first end positioned farther from the channel area, of the first end and a second end of the first auxiliary electrode; a second gate insulation film portion disposed to cover a second end positioned farther from the channel area, of a first end and the second end of the second auxiliary electrode; and a third gate insulation film portion positioned on the channel area, wherein the first electrode is positioned on an upper surface and a side surface of the first gate insulation film portion and contacts a portion of an upper surface of the first auxiliary electrode on the side surface of the first gate insulation film portion, wherein the second electrode is positioned on an upper surface and a side surface of the second gate insulation film portion and contacts a portion of an upper surface of the second auxiliary electrode on the side surface of the second gate insulation film portion, and wherein the third electrode is positioned on an upper surface of the third gate insulation film portion.

Furthermore, the first electrode includes a first lower electrode and a first upper electrode electrically connected to each other, wherein the second electrode includes a second lower electrode and a second upper electrode electrically connected to each other, wherein the third electrode includes a third lower electrode and a third upper electrode electrically connected to each other, wherein the first lower electrode, the second lower electrode, and the third lower electrode commonly include a first metal, and wherein the first upper electrode, the second upper electrode, and the third upper electrode commonly include a second metal different from the first metal.

Furthermore, the first electrode includes a first lower electrode and a first upper electrode electrically connected to each other,

wherein the second electrode includes a second lower electrode, a second additional capacitor electrode, and a second upper electrode electrically connected to each other, wherein the third electrode includes a third lower electrode and a third upper electrode electrically connected to each other, wherein the first lower electrode, the second lower electrode, and the third lower electrode commonly include a first metal, wherein the first upper electrode, the second upper electrode, and the third upper electrode commonly include a second metal different from the first metal, and wherein the second additional capacitor electrode includes a third metal different from the first metal and the second metal.

Furthermore, the display panel may further comprise a light shield disposed between the substrate and a buffer layer and overlapping with the channel area, wherein the light shield includes a lower light shield and an upper light shield on the lower light shield, wherein the lower light shield includes the first metal included in the first lower electrode, the second lower electrode, or the third lower electrode, and wherein the upper light shield includes the second metal included in the first upper electrode, the second upper electrode, or the third upper electrode.

Furthermore, the first lower electrode or the second lower electrode is connected to the upper light shield through a through hole of the buffer layer and the gate insulation film.

Furthermore, the display panel may further comprise a driving transistor disposed in a display area and including the first active layer, the first conductor, the second conductor, the first auxiliary electrode, the first electrode, the second electrode, and the third electrode; a storage capacitor connected between the first electrode and the third electrode of the driving transistor; and a light shield disposed between the substrate and a buffer layer and overlapping with the channel area, wherein the storage capacitor includes a first capacitor electrode, a second capacitor electrode positioned on the first capacitor electrode, and a third capacitor electrode positioned on the second capacitor electrode, wherein the buffer layer is positioned between the first capacitor electrode and the second capacitor electrode, and wherein the gate insulation film is positioned between the second capacitor electrode and the third capacitor electrode.

Furthermore, the first capacitor electrode includes a metal included in the light shield, wherein the second capacitor electrode includes an semiconductor material film and a conductive oxide film on the semiconductor material film, wherein the semiconductor material film includes an oxide semiconductor included in the active layer, wherein the conductive oxide film includes a conductive material included in the first conductor and the second conductor, and wherein the third capacitor electrode includes a metal included in the third electrode.

Furthermore, the second capacitor electrode further includes an additional metal film disposed on the metal film, and the additional metal film includes a metal included in the first auxiliary electrode.

Furthermore, the second capacitor electrode further includes an additional metal film disposed on the metal film, and the additional metal film includes a metal included in the first auxiliary electrode.

Furthermore, the display panel may further comprise a second active layer spaced apart from the first active layer, wherein the second active layer is included in the second capacitor electrode.

Furthermore, the first active layer further includes a third area disposed between the first area and the channel area and a fourth area disposed between the second area and the channel area, and

wherein the first area and the second area are non-conductive areas, and the third area and the fourth area are conductive areas.

In another aspect of the present disclosure, a display device includes a first active layer disposed on a substrate and including a channel area, a first area positioned on a first side of the channel area, and a second area positioned on a second side of the channel area, a first conductor disposed on the first area, a second conductor disposed on the second area, a first auxiliary electrode disposed on the first conductor, a first electrode on the first auxiliary electrode, a second electrode on the second conductor, and a third electrode overlapping with the channel area, wherein an area where the first auxiliary electrode is disposed includes a repair area.

According to various aspects of the disclosure, there may be provided a display panel and a display device capable of preventing instantaneous ghosting on panel by including auxiliary electrodes in a pad area on the active layer.

According to various aspects of the disclosure, there may be provided a display panel and a display device capable of preventing instantaneous ghosting on panel while facilitating a subpixel repair process through cutting the active layer by including a plurality of auxiliary electrodes disposed on the active layer.

It is to be understood that in addition to the effects of the present disclosure as mentioned above, additional advantages and features of the present disclosure will be clearly understood by those skilled in the art from the above description of the present disclosure.

### BRIEF DESCRIPTION OF THE DRAWINGS

The above and other features and advantages of the present disclosure will be more clearly understood from the following detailed description, taken in conjunction with the accompanying drawings, in which:

FIG. 1 is a view illustrating a system configuration of a display device 100 according to exemplary aspects of the disclosure;

FIG. 2 is an equivalent circuit diagram illustrating a subpixel SP of a display device 100 according to exemplary aspects of the disclosure;

FIG. 3 is another equivalent circuit diagram illustrating a subpixel SP of a display device 100 according to exemplary aspects of the disclosure;

FIG. 4 is a view illustrating a light shield LS in a subpixel SP of a display device 100 according to exemplary aspects of the disclosure;

FIGS. 5 and 6 are cross-sectional views illustrating transistor structures according to exemplary aspects of the disclosure;

FIG. 7 is a view illustrating a portion of an active area in a display panel according to exemplary aspects of the disclosure;

FIG. 8 is a cross-sectional view taken along line A-B of FIG. 7.

FIG. 9 is a cross-sectional view taken along line C-D of FIG. 7.

FIG. 10 is a plan view illustrating a pad area of an active area in a display panel according to exemplary aspects of the disclosure; and

FIG. 11 is a cross-sectional view taken along line E-F of FIG. 10.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and features of the present disclosure, and a method of achieving them will become apparent with reference to the aspects described below in detail in conjunction with the accompanying drawings. However, the present disclosure is not limited to the aspect to be disclosed below and is implemented in different and various forms. The aspects bring about the complete disclosure of the present disclosure and are only provided to make those skilled in the art understand the scope of the present disclosure. Further, the present disclosure is only defined by the scope of the claims and their equivalents.

In the following description of examples or aspects of the disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the disclosure, detailed descriptions of well-known functions and components incorporated herein will be omitted or may be briefly provided when it is determined that the description may make the subject matter in some aspects of the disclosure rather unclear. The terms such as “including”, “having”, “comprising” “containing”, “constituting” “make up of”, “consist of” and “formed of” used herein are generally intended to allow other components to be added unless the terms are used with the term such as “only”. As used herein, singular forms are intended to include plural forms unless the context clearly indicates otherwise.

The shapes, sizes, areas, ratios, angles, numbers, and the like illustrated in the accompanying drawings for describing various aspects of the present disclosure may be merely examples, and the present disclosure is not limited thereto.

When the position relation between two parts is described using the terms such as “on”, “above”, “over”, “below”, “under”, “beside”, “beneath”, “near”, “close to,” “adjacent to”, “on a side of”, “next” or the like, one or more parts may be positioned between the two parts unless the terms are used with the term such as “immediately” or “directly”.

Spatially relative terms, such as “under,” “below,” “beneath”, “lower,” “over,” “upper” and the like, may be used herein for ease of description to describe one element or feature's relationship to another element (s) or feature (s) as illustrated in the figures. It will be understood that the spatially relative terms may encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” may encompass both an orientation of below and above. Similarly, the exemplary term “above” or “over” may encompass both an orientation of “above” and “below”.

In describing elements, terms, such as “first”, “second”, “A”, “B”, “A”, or “B” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “adhered to”, “joined to”, “contacts or overlaps” etc. a second element, it should be interpreted that, not only may the first element “be directly connected or coupled to” “be directly adhered to”, “be directly joined to”, or “directly contact or overlap” the second element, but a third element may also be “interposed” between the first and second elements, or the first and second elements may “be connected or coupled to”, “adhered to”, “joined to”, “contact or overlap”, etc. each other via a fourth element. Here, the second element may be included in at least one of two or more elements that “are connected or coupled to”, “adhered to”, “joined to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” “just” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors e.g., process factors, internal or external impact, noise, etc.) even when a relevant description is not specified. Further, the term “may” fully encompasses all the meanings of the term “may”.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

A term “device” used herein may refer to a display device including a display panel and a driver for driving the display panel. Examples of the display device may include an organic light emitting diode (OLED), and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including OLED and the like, but aspects of the present disclosure are not limited thereto.

A size and a thickness of each component illustrated in the drawing are illustrated for convenience of description, and the present disclosure is not limited to the size and the thickness of the component illustrated.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example aspects belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, various exemplary aspects of the disclosure are described in detail with reference to the accompanying drawings.

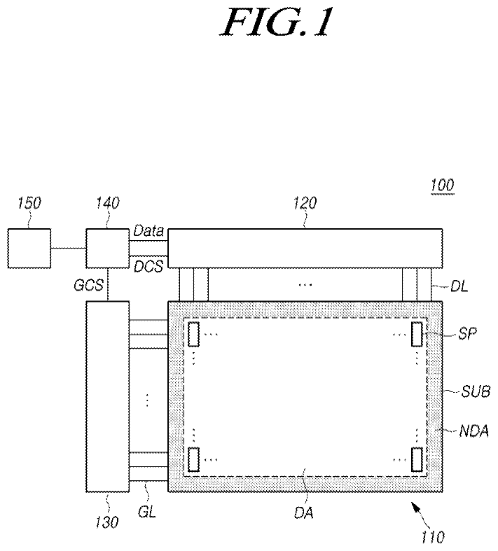

FIG. 1 is a view illustrating a system configuration of a display device 100 according to exemplary aspects of the disclosure. All the components of each display device according to all aspects of the present disclosure are operatively coupled and configured.

Referring to FIG. 1, a display device 100 according to exemplary aspects of the disclosure may include a display panel 110 and driving circuits for driving the display panel 110.

The driving circuits may include a data driving circuit 120 and a gate driving circuit 130, and the like. The display device 100 may further include a controller 140 controlling the data driving circuit 120 and the gate driving circuit 130.

The display panel 110 may include a substrate SUB and signal lines, such as a plurality of data lines DL and a plurality of gate lines GL, and the like disposed on the substrate SUB. The display panel 110 may include a plurality of subpixels SP connected to the plurality of data lines DL and the plurality of gate lines GL and may be located in areas where the gate lines GL and the data lines DL intersect each other.

The substrate SUB may include glass, plastic, or a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), or ciclic-olefin copolymer, cyclic olefin copolymer(COC), triacetylcellulose(TAC) film, polyvinyl alcohol(PVA) film, and polystyrene(PS), and aspects of the present disclosure are not limited thereto.

The display panel 110 may include a display area DA in which images are displayed and a non-display area NDA which is positioned outside of the display area DA and where no image is displayed. In the display panel 110, a plurality of subpixels SP for displaying images may be disposed in the display area DA, and the data driving circuit 120, the gate driving circuit 130, and controller 140 may be electrically connected or disposed in the non-display area NDA. Further, pad units for connection of integrated circuits or a printed circuit with the display panel 110 may be disposed in the non-display area NA.

The data driving circuit 120 may be controlled by the controller 140 to drive the plurality of data lines DL, and may supply data signals to the plurality of data lines DL. The gate driving circuit 130 is a circuit for driving the plurality of gate lines GL, and may sequentially supply gate signals to the plurality of gate lines GL arranged on the display panel 110, thereby controlling the driving timing of the plurality of subpixels SP. The controller 140 may supply a data control signal DCS to the data driving circuit 120 to control the operation timing of the data driving circuit 120. The controller 140 may supply a gate control signal GCS for controlling the operation timing of the gate driving circuit 130 to the gate driving circuit 130.

The controller 140 may control to start scanning according to a timing implemented in each frame, convert input image data input from the outside (e.g., other devices or other image providing sources such as host systems) into image data Data suited for the data signal format used in the data driving circuit 120, supply the image data Data to the data driving circuit 120, and control data driving to proceed at an appropriate time according to the scanning timing.

To control the gate driving circuit 130, the controller 140 may receive one or more of timing signals such as a vertical synchronous signal VSYNC, a horizontal synchronous signal HSYNC, an input data enable signal DE, a clock signal CLK, and the like from other devices, networks, or host systems, and output various gate control signals GCS including such as a gate start pulse GSP, a gate shift clock GSC, and a gate output enable signal GOE, and the like, but aspects of the present disclosure are not limited thereto.

To control the data driving circuit 120, the controller 140 may receive one or more of timing signals such as a vertical synchronous signal VSYNC, a horizontal synchronous signal HSYNC, an input data enable signal DE, a clock signal CLK, and the like from other devices, networks, or host systems, and output various data control signals DCS including, e.g., a source start pulse SSP, a source sampling clock SSC, and a source output enable signal SOE and the like, but aspects of the present disclosure are not limited thereto.

The controller 140 may be implemented as a separate component from the data driving circuit 120, or integrated with the data driving circuit 120, and implemented as an integrated circuit.

The data driving circuit 120 receives the image data DATA from the controller 140, convert the image data DATA into an analog data voltage Vdata, and supply data voltages to the plurality of data lines DL according to the timing at which the scan signal is applied through the gate line GL, thereby driving the plurality of data lines DL. The data driving circuit 120 is also referred to as a ‘source driving circuit.’

The data driving circuit 120 may include one or more source driver integrated circuit (SDICs). For example, each source driver integrated circuit SDIC may include a shift register, a latch circuit, a digital-to-analog converter, an output buffer, and the like.

For example, each source driver integrated circuit (SDIC) may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110. For example, each source driver integrated circuit SDIC may be directly disposed on the display panel 110. Alternatively, the source driver integrated circuit SDIC may be integrated and arranged on the display panel 110. Alternatively, each source driver integrated circuit SDIC may be implemented by a chip-on-film COF method. In this case, each source driver integrated circuit SDIC may be mounted on a film connected to the display panel 110, and may be electrically connected to the display panel 110 through wires on the film.

The gate driving circuit 130 may output a gate signal of a turn-on level voltage or a gate signal of a turn-off level voltage according to the control of the controller 140. The gate driving circuit 130 may sequentially drive the plurality of gate lines GL by sequentially supplying gate signals of the turn-on level voltage to the plurality of gate lines GL, thereby controlling the driving timing of the plurality of subpixels SP.

In some aspects, the gate driving circuit 130 may be connected with the display panel 110 by a tape automated bonding TAB method or connected to a conductive pad such as a bonding pad of the display panel 110 by a chip-on-glass COG or chip-on-panel COP method or may be connected with the display panel 110 according to a chip-on-film COF method. Alternatively, the gate driving circuit 130 may be formed in a gate in panel (GIP) type, in the non-display area NDA of the display panel 110. The gate driving circuit 130 may be disposed on or over the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type, or the like may be connected to the substrate SUB.

Meanwhile, at least one of the data driving circuit 120 and the gate driving circuit 130 may be disposed in the display area DA. For example, at least one of the data driving circuit 120 and the gate driving circuit 130 may be disposed not to overlap with the subpixels SP or to overlap with all or some of the subpixels SP.

When a specific gate line GL is selectively driven by the gate driving circuit 130, the data driving circuit 120 may convert the image data Data received from the controller 140 into an analog data voltage and supply it resulting from the converting to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides (e.g., the upper portion, the lower portion, a left side, and a right side) of the display panel 110, but aspects of the present disclosure are not limited thereto.

The gate driving circuit 130 may be connected to one side (e.g., a left or right side) of the display panel 110. Depending on the driving scheme or the panel design scheme, gate driving circuits 130 may be connected with both the sides (e.g., both the left and right sides) of the display panel 110, or two or more of the four sides (e.g., an upper portion, a lower portion, the left side, and the right side) of the display panel 110, but aspects of the present disclosure are not limited thereto.

The controller 140 may be a timing controller used in typical display technology, a control device that may additionally perform other control functions as well as the typical functions of the timing controller, or a control device other than the timing controller, or may be a circuit in the control device. In some aspects, the controller 140 may be one or more other control circuits different from the timing controller or implemented as various circuits or electronic components, such as an integrated circuit (IC), a field programmable gate array (FPGA), an application specific integrated circuit (ASIC), a processor or the like, but aspects of the present disclosure are not limited thereto.

The controller 140 may be mounted on a printed circuit board or a flexible printed circuit, or the like and may be electrically connected with the data driving circuit 120 and the gate driving circuit 130 through the printed circuit board or the flexible printed circuit, or the like.

The display device 100 according to exemplary aspects of the disclosure may be a display including a backlight unit, such as a liquid crystal display (LCD), and the like, or may be a self-emission display, such as an organic light-emitting diode (OLED) display, a quantum dot display, or a micro light-emitting diode (LED) display, and the like, but aspects of the present disclosure are not limited to, a plasma display panel device PDP, and an electroluminescence display device ELD and the like may be applicable as well.

If the display device 100 according to exemplary aspects of the disclosure is an OLED display, each subpixel SP may include an organic light-emitting diode (OLED), which by itself emits light, as the light-emitting element. If the display device 100 according to exemplary aspects of the disclosure is a quantum dot display, each subpixel SP may include a light-emitting element formed of a quantum dot, which is a self-luminous semiconductor crystal. If the display device 100 according to exemplary aspects of the disclosure is a micro LED display, each subpixel SP may include a micro LED, which is self-emissive and formed of an inorganic material, as the light-emitting element, but aspects of the present disclosure are not limited thereto.

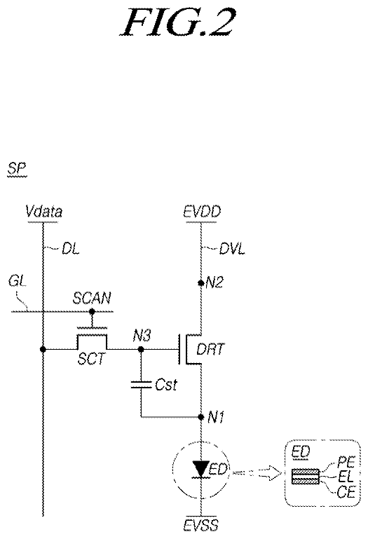

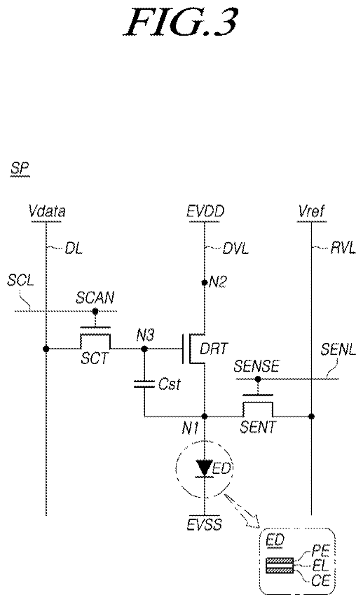

FIG. 2 illustrates an equivalent circuit of a subpixel SP of a display device 100 according to exemplary aspects of the disclosure, and FIG. 3 illustrates another equivalent circuit of a subpixel SP of the display device 100 according to exemplary aspects of the disclosure.

Referring to FIG. 2, each of a plurality of subpixels SP disposed on a display panel 110 of a display device 100 according to aspects of the disclosure may include a light-emitting element ED, a driving transistor DRT, a scanning transistor SCT, and a storage capacitor Cst.

Referring to FIG. 2, the light-emitting element ED may include a pixel electrode PE and a common electrode CE and may include a light-emitting layer EL positioned between the pixel electrode PE and the common electrode CE.

The pixel electrode PE of the light-emitting element ED may be an electrode disposed in each subpixel SP, and the common electrode CE may be an electrode commonly disposed in all the subpixels SP. Here, the pixel electrode PE may be an anode electrode, and the common electrode CE may be a cathode electrode. Conversely, the pixel electrode PE may also be a cathode electrode, and the common electrode CE may be an anode electrode.

For example, the light-emitting element ED may be an organic light-emitting diode (OLED), a light-emitting diode (LED), or a quantum dot light-emitting element, but aspects of the present disclosure are not limited thereto.

The driving transistor DRT is a transistor for driving the light-emitting element ED, and may include a first node N1, a second node N2, and a third node N3.

The first node Ni of the driving transistor DRT may be the source node (source electrode) or the drain node (drain electrode) of the driving transistor DRT, and may be electrically connected to the pixel electrode PE of the light-emitting element ED. The second node N2 of the driving transistor DRT may be the drain node (drain electrode) or the source node (source electrode) of the driving transistor DRT and be electrically connected to a driving voltage line DVL supplying the driving voltage EVDD. The third node N3 of the driving transistor DRT may be the gate node (gate electrode) of the driving transistor DRT and be electrically connected to the source node or the drain node of the scanning transistor SCT. If driving transistor DRT is an n-type transistor, the gate electrode turn-on level voltage thereof may be a high level voltage. If the driving transistor DRT is a p-type transistor, gate electrode turn-on level voltage thereof may be a low level voltage.

The scanning transistor SCT may be controlled by a scanning gate signal SCAN, which is a type of gate signal, and may be connected between the third node N3 (e.g., gate electrode) of the driving transistor DRT and the data line DL. In other words, the scanning transistor SCT may be turned on or off according to the scanning gate signal SCAN supplied from the scanning gate line SCL, which is a type of the gate line GL, controlling the electrical connection between the data line DL and the third node N3 of the driving transistor DRT.

The scanning transistor SCT may be turned on by the scanning gate signal SCAN having a turn-on level voltage and transfer the data voltage Vdata supplied from the data line DL to the third node N3 of the driving transistor DRT.

If the scanning transistor SCT is an n-type transistor, the turn-on level voltage of the scanning gate signal SCAN may be a high level voltage. If the scanning transistor SCT is a p-type transistor, the turn-on level voltage of the scanning gate signal SCAN may be a low level voltage.

The storage capacitor Cst may be electrically connected between the third node N3 and first node Ni of the driving transistor DRT. The storage capacitor Cst is charged with the quantity of electric charge corresponding to the voltage difference between both ends thereof (e.g., the third node N3 and first node Ni of the driving transistor DRT) and serves to maintain the voltage difference between both ends for a predetermined frame time. Accordingly, during the predetermined frame time, the corresponding subpixel SP may emit light.

Referring to FIG. 3, each of the plurality of subpixels SP disposed on the display panel 110 of the display device 100 according to exemplary aspects of the disclosure may further include a sensing transistor SENT.

The sensing transistor SENT may be controlled by a sensing gate signal SENSE, which is another type of gate signal, and may be connected between the first node Ni of the driving transistor DRT and the reference voltage line RVL. In other words, the sensing transistor SENT may be turned on or off according to the sensing gate signal SENSE supplied from the sensing gate line SENL, which is another type of the gate line GL, controlling the connection between the reference voltage line RVL and the first node N1 of the driving transistor DRT.

The sensing transistor SENT may be turned on by the sensing gate signal SENSE having a turn-on level voltage and transfer a reference voltage Vref supplied from the reference voltage line RVL to the first node N1 of the driving transistor DRT.

The sensing transistor SENT may be turned on by the sensing gate signal SENSE having a turn-on level voltage, transferring the voltage of the first node N1 of the driving transistor DRT to the reference voltage line RVL.

If the sensing transistor SENT is an n-type transistor, the turn-on level voltage of the sensing gate signal SENSE may be a high level voltage. If the sensing transistor SENT is a p-type transistor, the turn-on level voltage of the sensing gate signal SENSE may be a low level voltage.

The function in which the sensing transistor SENT transfers the voltage of the first node N1 of the driving transistor DRT to the reference voltage line RVL may be used upon driving to sense at least one characteristic value of the subpixel SP. In this case, the voltage transferred to the reference voltage line RVL may be a voltage for calculating the at least one characteristic value of the subpixel SP or a voltage reflecting the characteristic value of the subpixel SP. Herein, the at least one characteristic value of the sub-pixel SP may be a characteristic value of the driving transistor DRT or the light-emitting element ED. The characteristic value of the driving transistor DRT may include a threshold voltage and/or mobility of the driving transistor DRT. The characteristic value of the light emitting element ED may include a threshold voltage of the light emitting element ED.

In the disclosure, for convenience of description, each of the driving transistor DRT, the scanning transistor SCT, and the sensing transistor SENT is an n-type transistor. However, aspects of the present disclosure are not limited thereto, and e

The storage capacitor Cst is not a parasitic capacitor (e.g., Cgs or Cgd) which is an internal capacitor existing between the gate node and the source node (or drain node) of the driving transistor DRT, but may be an external capacitor intentionally designed outside the driving transistor DRT.

The scanning gate line SCL and the sensing gate line SENL may be different gate lines GL. In this case, the scanning gate signal SCAN and the sensing gate signal SENSE may be separate gate signals, and the on-off timings of the scanning transistor SCT and the on-off timings of the sensing transistor SENT in one subpixel SP may be independent. In other words, the on-off timings of the scanning transistor SCT and the on-off timings of the sensing transistor SENT in one subpixel SP may be the same or different from each other.

Alternatively, the scanning gate line SCL and the sensing gate line SENL may be the same gate line GL. In other words, the gate node of the scanning transistor SCT and the gate node of the sensing transistor SENT in one subpixel SP may be connected with one gate line GL. In this case, the scanning gate signal SCAN and the sensing gate signal SENSE may be the same gate signals, and the on-off timings of the scanning transistor SCT and the on-off timings of the sensing transistor SENT in one subpixel SP may be the same.

The structures of the subpixel SP shown in FIGS. 2 and 3 are merely examples, and various changes may be made thereto, e.g., such as including one or more transistors or one or more capacitors. For example, a number of transistors in the subpixel SP of the present disclosure may be three or more, and a number of capacitors may be one or more, for example, a pixel circuit of the subpixel SP of the present disclosure also may be a 3T1C pixel circuit including three transistors and one capacitor, a 3T2C pixel circuit including three transistors and two capacitors, a 5T1C pixel circuit including five transistors and one capacitor, a 5T2C pixel circuit including five transistors and two storage capacitors, a 7T1C pixel circuit including seven transistors and one capacitor, a 7T2C pixel circuit including seven transistors and two storage capacitors, or the like, but aspects of the present disclosure are not limited thereto.

Meanwhile, each transistor according to the aspects of the present disclosure may be thin film transistor TFT using an oxide semiconductor material or polycrystalline silicon semiconductor as an active layer. For example, the oxide semiconductor material may be formed of one of indium gallium zinc oxide (IGZO), indium zinc oxide (IZO), indium gallium tin oxide (IGTO), and indium gallium oxide (IGO), but aspects of the present disclosure are not limited thereto.

Although the subpixel structure is described in connection with FIGS. 2 and 3 under the assumption that the display device 100 is a self-emission display device, if the display device 100 is a liquid crystal display, each subpixel SP may include a transistor and a pixel electrode.

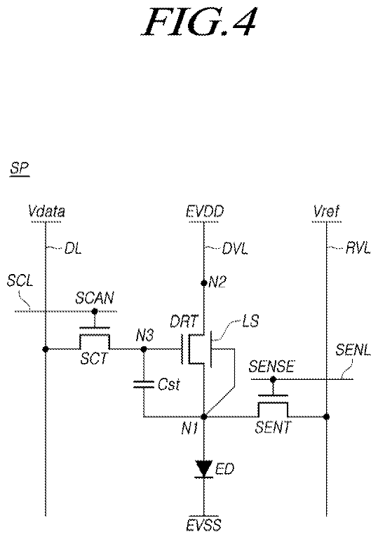

FIG. 4 is a view illustrating a light shield LS in a subpixel SP of a display device 100 according to exemplary aspects of the disclosure.

Referring to FIG. 4, in the subpixel SP of the display device 100 according to exemplary aspects of the disclosure, the driving transistor DRT may have intrinsic characteristics, such as threshold voltage and mobility. When the intrinsic characteristics of the driving transistor DRT change, the current driving capability (current supply capability) of the driving transistor DRT changes, and thus the light-emitting characteristics of the corresponding subpixel SP may also change.

The device characteristics (e.g., threshold voltage, mobility, etc.) of the driving transistor DRT may change as the driving time of the driving transistor DRT elapses. Further, when light is radiated to the driving transistor DRT, particularly to the channel area of the driving transistor DRT, the device characteristics (e.g., threshold voltage, mobility, etc.) of the driving transistor DRT may change.

Therefore, as illustrated in FIG. 4, to reduce or minimize a change in device characteristics (e.g., a change in threshold voltage, change in mobility, etc.) of the driving transistor DRT, a light shield LS may be formed near the driving transistor DRT. For example, the light shield LS may be formed under at least the channel area of the driving transistor DRT.

Meanwhile, not only does it block light from penetrating the substrate and reaching the driving transistor DRT, the light shield LS may also serve as a body of the driving transistor DRT by being formed under at least the channel area of the driving transistor DRT.

A body effect may occur in the driving transistor DRT. To reduce or minimize the body effect, the light shield LS serving as the body of the driving transistor DRT may be electrically connected to the first node Ni. Here, the first node N1 of the driving transistor DRT may be the source node of the driving transistor DRT.

Meanwhile, the light shield LS may be disposed not only under the channel area of the driving transistor DRT, but also under the channel area of another transistor (e.g., SCT or SENT).

In the display area DA of the display panel 110 according to aspects of the disclosure, transistors DRT, SCT, and SENT may be disposed in each subpixel SP. When the gate driving circuit 130 is formed in a gate in panel (GIP) type in the non-display area NDA of the display panel 110 according to aspects of the disclosure, the plurality of transistors included in the GIP-type gate driving circuit 130 may be disposed in the non-display area NDA of the display panel 110.

As such, a plurality of transistors may be disposed in the display panel 110 according to aspects of the disclosure. These transistors (in particular, the driving transistor DRT in each subpixel SP) may deteriorate as the driving time elapses.

Meanwhile, the conventional display devices may produce instantaneous ghosting while being driven. For example, instantaneous ghosting may occur where the grayscale is sharply changed during screen switch.

The inventors of the disclosure have identified through experiments and analysis that the instantaneous ghosting is related to the deterioration of the transistor, and invented a structure and process capable of mitigating the deterioration of the transistor. In particular, the inventors of the disclosure have identified that instantaneous ghosting is caused by deterioration of the transistor and invented a repair structure and process capable of mitigating or minimizing the deterioration.

A display device 100 capable of suppressing or minimizing the occurrence of instantaneous ghosting and, even when occurring, mitigating instantaneous ghosting even under driving conditions or driving environments in which instantaneous ghosting may occur and a manufacturing method thereof are described below in greater detail.

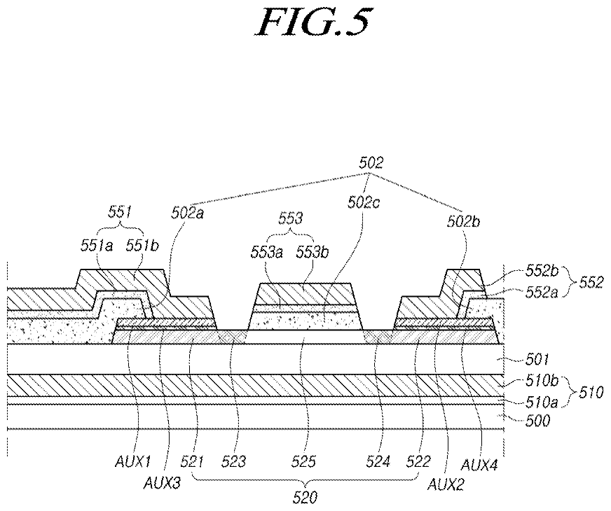

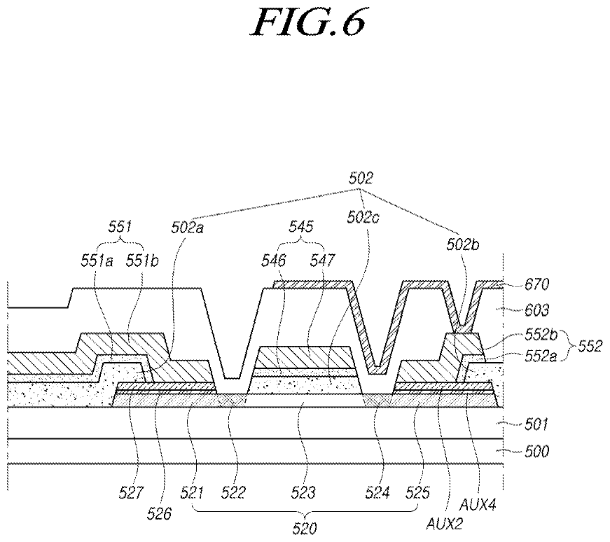

FIGS. 5 and 6 are cross-sectional views illustrating transistor structures according to exemplary aspects of the disclosure.

A display panel 110 according to exemplary aspects of the disclosure may include a display area DA in which images are displayed and a non-display area NDA (in which an image is not displayed) different from the display area DA. The non-display area NDA may be disposed in the vicinity of the display area DA or to surround the display area DA. A plurality of transistors and a plurality of capacitors may be disposed in the display area DA and/or the non-display area NDA.

Transistors disposed on the display panel 110 according to aspects of the disclosure may be transistors DRT, SCT, and SENT disposed in each subpixel SP in the display area DA.

Further, the transistors disposed on the display panel 110 according to aspects of the disclosure may be transistors included in the GIP-type gate driving circuit 130 formed in the non-display area NDA.

Further, the capacitor disposed on the display panel 110 according to aspects of the disclosure may be the storage capacitor Cst included in each subpixel SP in the display area DA and may also be the capacitor included in the GIP-type gate driving circuit 130 formed in the non-display area NDA.

Hereinafter, as a transistor for describing a transistor structure according to aspects of the disclosure, the driving transistor DRT in each subpixel SP in the display area DA is taken as an example and, as a capacitor for describing a capacitor structure according to aspects of the disclosure, the storage capacitor Cst in the subpixel SP is taken as an example.

Referring to FIGS. 5 and 6, the display panel 110 of the display device 100 according to aspects of the disclosure may include a substrate 500, a buffer layer 501 on the substrate 500, a first active layer 520 on the buffer layer 501, a gate insulation film 502 on the first active layer 520, and a third electrode 553 on the gate insulation film 502, and may further include a light shield 510 disposed under the first active layer 520.

FIG. 5 illustrates a structure in which the light shield 510 is disposed under the first active layer 520, but the structure of the display device 100 according to aspects of the disclosure is not limited thereto. As illustrated in FIG. 6, the light shield 510 may not be disposed under the first active layer 520. For example, the light shield 510 may be omitted as necessary.

The transistor TR disposed on the display panel 110 according to aspects of the disclosure may be a driving transistor DRT, but is not limited thereto.

For example, the transistor described herein may be a scanning transistor SCT or a sense transistor SENT disposed in the display area DA, or may be a transistor disposed in the non-display area NDA.

Referring to FIGS. 5 and 6, the transistor TR may include a first electrode 551, a second electrode 552, a third electrode 553, and a first active layer 520. Here, the first electrode 551 may be a source electrode of the transistor TR, and the second electrode 552 may be a drain electrode of the transistor TR. Alternatively, the first electrode 551 may be a drain electrode of the transistor TR, the second electrode 552 may be a source electrode of the driving transistor TR, and third electrode 553 may be a gate electrode of the transistor TR.

The first active layer 520 may include a first area 521, a second area 522, a third area 523, a fourth area 524, and a channel area 525.

Specifically, the first active layer 520 may include a channel area 525 overlapping with the third electrode 553, a first area 521 positioned on a first side of the channel area 525, and a second area 522 positioned on a second side of the channel area 525. Further, the first active layer 520 may include a third area 523 disposed between the first area 521 and the channel area 525, and a fourth area 524 disposed between the second area 522 and the channel area 525.

The channel area 525 may overlap with the third electrode 553. A gate insulation film 502 may be disposed between the channel area 525 and the third electrode 553 (e.g., gate electrode).

The first area 521, the second area 522, and the channel area 525 may be non-conductive areas. The third area 523 and the fourth area 524 may be conductive areas.

The first active layer 520 may include an oxide semiconductor material. The oxide semiconductor material is a semiconductor material that controls conductivity and adjusts a band gap through doping an oxide material, and may generally be a transparent semiconductor material having a wide band gap. The oxide semiconductors may be made of a metal oxide such as zinc (Zn), indium (In), gallium (Ga), tin (Sn), and titanium (Ti) or a combination of a metal such as zinc (Zn), indium (In), gallium (Ga), tin (Sn), and titanium (Ti) or its oxide. Specifically, the oxide semiconductor material may include, e.g., indium gallium zinc oxide (IGZO), zinc oxide (ZnO), cadmium oxide (CdO), indium oxide (InO), zinc tin oxide (ZTO), zinc indium tin oxide (ZITO), indium gallium zinc tin oxide (IGZTO), indium gallium tin oxide (IGTO), or indium gallium oxide (IGO). When the first active layer 520 is an oxide semiconductor material, the transistor TR including the first active layer 520 is referred to as an oxide thin film transistor TFT.

In FIGS. 5 and 6, only a structure in which the first active layer 520 is a single layer is illustrated, but the structure of the transistor TR according to aspects of the disclosure is not limited thereto. The first active layer 520 may include two or more layers. For example, when the first active layer 520 includes two or more layers, the two or more layers may be formed of the same semiconductor material or multilayer may be formed of two or more different semiconductor materials(e.g., the oxide semiconductor material and the polycrystalline semiconductor material), the polycrystalline semiconductor layer may be formed of a low temperature poly silicon (LTPS) having a high mobility, but is not limited thereto.

The third electrode 553 may be disposed on the gate insulation film 502 disposed on the first active layer 520 and may overlap with the channel area 525 of the first active layer 520.

The first electrode 551 may be electrically connected to the first area 521 of the first active layer 520. The second electrode 552 may be electrically connected to the second area 522 of the first active layer 520.

Each of the first electrode 551, the second electrode 552, and the third electrode 553 may be a single layer or more layers. For example, each of the first electrode 551, the second electrode 552, and the third electrode 553 may include copper (Cu), aluminum (Al), molybdenum (Mo), titanium (Ti), chromium (Cr), molybdenum titanium (MoTi), or the like.

When at least one of the first electrode 551, the second electrode 552, and the third electrode 553 includes two or more layers, at least one of the first electrode 551, the second electrode 552, and the third electrode 553 may include a lower electrode and an upper electrode electrically connected to each other.

The lower electrode may include a first metal, and the upper electrode may include a second metal different from the first metal. For example, the first metal may include molybdenum (Mo), titanium (Ti), molydenumtitanium (MoTi), or the like. The second metal may include copper (Cu), aluminum (Al), or the like. However, aspects of the present disclosure are not limited thereto, the lower electrode and the upper electrode may also include a same metal. Described below is an example in which the first metal is molydenum·titanium (MoTi), and the second metal is copper (Cu).

Referring to FIGS. 5 and 6, the first electrode 551 may include a first lower electrode 551a and a first upper electrode 551b electrically connected to each other. The first lower electrode 551a may include a first metal (e.g., MoTi), and the first upper electrode 551b may include a second metal (e.g., Cu) different from the first metal.

Referring to FIGS. 5 and 6, the second electrode 552 may include a second lower electrode 552a and a second upper electrode 552b electrically connected to each other. The second lower electrode 552a may include a first metal (e.g., MoTi), and the second upper electrode 552b may include a second metal (e.g., Cu).

Referring to FIGS. 5 and 6, the third electrode 553 may include a third lower electrode 553a and a third upper electrode 553b electrically connected to each other. The third lower electrode 553a may include a first metal (e.g., MoTi), and the third upper electrode 553b may include a second metal (e.g., Cu).

As described above, the first lower electrode 551a, the second lower electrode 552a, and the third lower electrode 553a may include the first metal in common, and the first upper electrode 551b, the second upper electrode 552b, and the third upper electrode 553b may include the second metal different from the first metal in common. In this case, he first lower electrode 551a, the second lower electrode 552a, and the third lower electrode 553a may be simultaneously formed in a same process, and the first upper electrode 551b, the second upper electrode 552b, and the third upper electrode 553b may be simultaneously formed in a same process.

Referring to FIGS. 5 and 6, the transistor TR disposed on the display panel 110 according to exemplary aspects of the disclosure may further include a first auxiliary electrode AUX1 on the first area 521 and a second auxiliary electrode AUX2 on the second area 522. A third auxiliary electrode AUX3 (first conductor) may be disposed between the first area 521 and the first auxiliary electrode AUX1, and a fourth auxiliary electrode AUX4 (second conductor) may be disposed between the second area 522 and the second auxiliary electrode AUX2.

The first auxiliary electrode AUX1 and the third auxiliary electrode AUX3 may be positioned between the first area 521 and the first electrode 551 to electrically connect the first area 521 and the first electrode 551. The second auxiliary electrode AUX2 and the fourth auxiliary electrode AUX4 may be positioned between the second area 522 and the second electrode 552 to electrically connect the second area 522 and the second electrode 552.

The conductive material included in each of the first auxiliary electrode AUX1 and the second auxiliary electrode AUX2 may include a metal included in the first electrode 551, the second electrode 552, or the third electrode 553. For example, the metal included in the first electrode 551, the second electrode 552, or the third electrode 553 may be copper(Cu), aluminum (Al), molybdenum (Mo), titanium (Ti), chromium (Cr), molydenumtitanium (MoTi), or the like, but aspects of the present disclosure are not limited thereto.

When the first electrode 551, the second electrode 552, or the third electrode 553 has a double metal structure, the conductive material included in each of the first auxiliary electrode AUX1 and the second auxiliary electrode AUX2 may include the first metal (e.g., MoTi) included in the first lower electrode 551a, the second lower electrode 552a, or the third lower electrode 553a, but aspects of the present disclosure are not limited thereto.

In other words, the first auxiliary electrode AUX1 and the second auxiliary electrode AUX2 may be formed of a pure metal or an alloy form (including two or more metal materials) in which pure metal components are mixed, rather than metal oxides. Accordingly, the first auxiliary electrode AUX1 and the second auxiliary electrode AUX2 may be opaque.

Alternatively, the conductive material included in each of the third auxiliary electrode AUX3 and the fourth auxiliary electrode AUX4 may include a conductive oxide including oxygen. For example, the conductive oxide may include at least one of a transparent conductive oxide (TCO), a nitric oxide, an organic material, or the like. For example, the transparent conductive oxide TCO may include one or more of indium zinc oxide (IZO), indium gallium tin oxide (IGTO), and indium gallium oxide (IGO), indium tin oxide (ITO), indium-gallium-zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO). The nitric oxide may include zinc oxynitride (ZnON) or the like, but aspects of the present disclosure are not limited thereto.

Referring to FIGS. 5 and 6, the gate insulation film 502 may include a first gate insulation film portion 502a, a second gate insulation film portion 502b, and a third gate insulation film portion 502c.

Referring to FIGS. 5 and 6, the first gate insulation film portion 502a may be disposed to cover a first end of the first auxiliary electrode AUX1 that is positioned farther from the channel area 525 of the first active layer 520, of the first end and the second end.

The second gate insulation film portion 502b may be disposed to cover a second end of the second auxiliary electrode AUX2 that is positioned further away from the channel area 525 of the first active layer 520, of the first end and the second end.

Referring to FIGS. 5 and 6, the first gate insulation film portion 502a and the second gate insulation film portion 502b may not overlap with the channel area 525 of the first active layer 520. The third gate insulation film portion 502c may be positioned on the channel area 525 of the first active layer 520 and overlap with the channel area 525 of the first active layer 520.

Referring to FIGS. 5 and 6, the first electrode 551 may be positioned on the upper surface and the side surface of the first gate insulation film portion 502a, and may contact a portion of the upper surface of the first auxiliary electrode AUX1 on the side surface of the first gate insulation film portion 502a. The second electrode 552 may be positioned on the upper surface and the side surface of the second gate insulation film portion 502b, and may contact a portion of the upper surface of the second auxiliary electrode AUX2 on the side surface of the second gate insulation film portion 502b. The third electrode 553 may be positioned on an upper surface of the third gate insulation film portion 502c.

As described above, the first auxiliary electrode AUX1 and the third auxiliary electrode AUX3 may be auxiliary electrodes that are media of electrical connection between the first area 521 and the first electrode 551, and the second auxiliary electrode AUX2 and the fourth auxiliary electrode AUX4 may be auxiliary electrodes that are media of electrical connection between the second area 522 and the second electrode 552.

As the third auxiliary electrode AUX3 is disposed between the first auxiliary electrode AUX1 and the first area 521, and the fourth auxiliary electrode AUX4 is disposed between the second auxiliary electrode AUX2 and the second area 522, it is possible to prevent or reduce the first active layer 520 from being damaged in the process of forming the first and second auxiliary electrodes AUX1 and AUX2.

Specifically, in the first auxiliary electrode AUX1 and the second auxiliary electrode AUX2, the third and fourth auxiliary electrode AUX3 and AUX4 material layers may be formed on the material of the first active layer 520, and the first and second auxiliary electrode AUX1 and AUX2 material layers may be formed on the third and fourth auxiliary electrode AUX3 and AUX4 material layers.

Thereafter, by etching and patterning the first and second auxiliary electrodes AUX1 and AUX2 material layers and the third and fourth auxiliary electrodes AUX3 and AUX4 material layers, the first and second auxiliary electrodes AUX1 and AUX2 and the third and fourth auxiliary electrodes AUX3 and AUX4 may be formed.

Each of the first and second auxiliary electrodes AUX1 and AUX2 formed through such a process may have a thickness of 100 Å to 200 Å or 120 to 180 Å, or be adjusted to a 140 to 160 Å.

When the thicknesses of the first and second auxiliary electrodes AUX1 and AUX2 are less than 100 Å, the film uniformity of the first and second auxiliary electrodes AUX1 and AUX2 may be reduced, and thus the electrical characteristics of the thin film transistor may be reduced. Further, at least one of the areas in which the first and second auxiliary electrodes AUX1 and AUX2 are disposed may be a repair area, and when the uniformity of the first and second auxiliary electrodes AUX1 and AUX2 is reduced and the first and second auxiliary electrodes AUX1 and AUX2 are not formed in some areas, the repair area may not be properly viewed.

When the thicknesses of the first and second auxiliary electrodes AUX1 and AUX2 exceed 200 Å, metal components of the first and second auxiliary electrodes may penetrate the first active layer 520 in the process (e.g., wet etching) of patterning the first and second auxiliary electrodes AUX1 and AUX2, thereby causing deterioration of the thin film transistor with the result of a decrease in reliability.

The thickness of each of the third and fourth auxiliary electrodes AUX3 and AUX4 may be 70 Å to 100 Å or be adjusted to 80 to 90 Å.

When the thicknesses of the third and fourth auxiliary electrodes AUX3 and AUX4 are less than 70 Å, the electrical conductivity of the third and fourth auxiliary electrodes AUX3 and AUX4 may be reduced, and it is difficult to prevent the first active layer 520 from being damaged in the process of forming the first and second auxiliary electrodes AUX1 and AUX2.

Further, the first and second auxiliary electrode AUX1 and AUX2 material layers and the third and fourth auxiliary electrode AUX3 and AUX4 material layers are formed through a simultaneous process, and the third and fourth auxiliary electrode AUX3 and AUX4 material layers include conductive oxides and thus have a lower etching speed than that of the first and second auxiliary electrode AUX1 and AUX2 material layers including only metal components. Accordingly, when the thickness of the third and fourth auxiliary electrodes AUX3 and AUX4 formed simultaneously with the formation of the first and second auxiliary electrodes AUX1 and AUX2 exceeds 100 Å, the first and second auxiliary electrode AUX1 and AUX2 material layers having a relatively high etching speed are over-etched, and thus the first and second auxiliary electrodes AUX1 and AUX2 may not be formed to a desired thickness.

Accordingly, the maximum value of the sum of the thickness of the first auxiliary electrode AUX1 and the thickness of the third auxiliary electrode AUX3 may be 300 Å, and the maximum value of the sum of the thickness of the second auxiliary electrode AUX2 and the thickness of the fourth auxiliary electrode AUX4 may also be 300 Å.

As illustrated in FIGS. 5 and 6, as the third auxiliary electrode AUX3 is disposed under the first auxiliary electrode AUX1 and the fourth auxiliary electrode AUX4 is disposed under the second auxiliary electrode AUX2, electrical reliability may be secured even if the thicknesses of the first and second auxiliary electrodes AUX1 and AUX2 are reduced.

Here, the thicknesses of each of the first and second auxiliary electrodes AUX1 and AUX2 may be larger than or equal to the thicknesses of each of the third and fourth auxiliary electrodes AUX3 and AUX4.

When the third and fourth auxiliary electrode AUX3 and AUX4 material layers are not present under the first and second auxiliary electrode AUX1 and AUX2 material layers, the first active layer 520 may be damaged in the process of forming or patterning the first and second auxiliary electrode AUX1 and AUX2 material layers.

In particular, some of the elements included in the first and second auxiliary electrode AUX1 and AUX2 material layers may remain on the surface of the first active layer 520 to cause the interface deterioration of the first active layer 520, which may cause instantaneous ghosting on the display panel.

For example, during screen switch, instantaneous ghosting may occur at a portion where the grayscale rapidly changes.

The inventors of the disclosure have identified through experiments and analysis that the instantaneous ghosting is related to the deterioration of the transistor, and invented a structure and process capable of mitigating or minimizing the deterioration of the transistor. In particular, the inventors of the disclosure have identified that the instantaneous ghosting is caused by the deterioration of the transistor in both directions, and have invented a structure and a process capable of mitigating or minimizing the deterioration in both directions.

Specifically, in the transistor TR according to aspects of the disclosure, the third and fourth auxiliary electrode AUX3 and AUX4 material layers are disposed under the first and second auxiliary electrode AUX1 and AUX2 material layers, so that the third and fourth auxiliary electrode AUX3 and AUX4 material layers protect the first active layer 520 in the process of forming or patterning the first and second auxiliary electrode AUX1 and AUX2 material layers, thus preventing damage to the first active layer 520.

Since the third and fourth auxiliary electrode AUX3 and AUX4 material layers include an oxide-based material like the first active layer 520, elements included in the third and fourth auxiliary electrode AUX3 and AUX4 material layers may not act as impurities on the surface of the first active layer 520. Accordingly, it is possible to prevent or minimize a phenomenon in which the interface of the first active layer 520 is deteriorated, and accordingly, instantaneous ghosting of the display panel may not occur.

To form each of the third and fourth auxiliary electrodes AUX3 and AUX4, formed in the etching process at the same time as the first and second auxiliary electrodes AUX1 and AUX2, to have an appropriate thickness (e.g., 70 Å to 100 Å), and to form the first and second auxiliary electrodes AUX1 and AUX2 to have an appropriate thickness (e.g., 100 Å to 200 Å), the content of elements included in the third and fourth auxiliary electrodes AUX3 and AUX4 may be adjusted, and accordingly, the etching speed of the material forming the third and fourth auxiliary electrodes AUX3 and AUX4 may be adjusted in the etching process (e.g., wet etching).

For example, when the third and fourth auxiliary electrodes AUX3 and AUX4 are formed of indium zinc oxide (IZO), the content ratio of indium (In) and zinc (Zn) may be 5:5 to 7:3, but aspects of the present disclosure are not limited thereto.

In the ratio of indium (In) to zinc (Zn), when the content of indium (In) is higher and the content of zinc (Zn) is lower (e.g., when the indium content:zinc content=8:2 to 9:1, etc., but not limited thereto), the etching speed of the third and fourth auxiliary electrode AUX3 and AUX4 material layers is very slow, and when the third and fourth auxiliary electrodes AUX3 and AUX4 are patterned in a desired thickness and shape, the first and second auxiliary electrode AUX1 and AUX2 material layers may be over-etched.

Further, in the ratio of indium (In) to zinc (Zn), when the content of indium (In) is lower and the content of zinc (Zn) is higher (e.g., when the indium content: zinc content=4:6 to 1:9, etc., but not limited thereto), the electrical characteristics of the third and fourth auxiliary electrodes AUX3 and AUX4 may be deteriorated.

The thickness of the first active layer 520 disposed under the third and fourth auxiliary electrodes AUX3 and AUX4 may range from 200 Å to 500 Å. When the thickness of the first active layer 520 is less than 200 Å, the uniformity of the first active layer 520 may be lowered. Further, when the thickness of the first active layer 520 exceeds 500 Å, the mobility may be lowered and the electrical characteristics of the thin film transistor may be deteriorated.

Referring to FIGS. 5 and 6, the buffer layer 501 may be formed to prevent moisture from permeating from the outside, and may include a single layer or more layers. For example, the buffer layer 501 may include various insulation film materials such as silicon nitride (SiNₓ), silicon dioxide (SiOₓ), and the like.

When the buffer layer 501 includes two layers, the buffer layer 501 may include a first buffer layer and a second buffer layer disposed on the first buffer layer. In this case, for example, the first buffer layer may include silicon nitride (SiNₓ), and the second buffer layer may include silicon dioxide (SiOₓ). Alternatively, the first buffer layer may include silicon dioxide (SiOₓ), and the second buffer layer may include silicon nitride (SiNₓ).

When the buffer layer 501 includes n layers (where n is an integer greater than 2), the 1st to nth buffer layer may be configured to include silicon nitride (SiNₓ) and silicon dioxide (SiOₓ) alternatively, but aspects of the present disclosure are not limited thereto.

The gate insulation film 502 positioned on the channel area 525 of the first active layer 520 may have a structure patterned on the first active layer 520 as illustrated in FIGS. 5 and 6, but aspects of the disclosure are not limited thereto, and the gate insulation film 502 may be disposed on the front surface of the first active layer 520.

The following description focuses primarily on a structure in which the gate insulation film 502 disposed on the first active layer 520 is patterned, as illustrated in FIGS. 5 and 6 for convenience of description.

Referring to FIGS. 5 and 6, the first auxiliary electrode AUX1 may be positioned on the whole or a portion of the first area 521 of the first active layer 520. The whole or a portion of the first auxiliary electrode AUX1 may be exposed through an opening (etch hole) of the gate insulation film 502. The first electrode 551 may be connected to the first auxiliary electrode AUX1 exposed through the opening (etch hole) of the gate insulation film 502. Accordingly, the first electrode 551 may be electrically connected to the first area 521 of the first active layer 520 through the first auxiliary electrode AUX1.

The second auxiliary electrode AUX2 may be positioned on the whole or a portion of the second area 522 of the first active layer 520. The whole or a portion of the second auxiliary electrode AUX2 may be exposed through another opening (etch hole) of the gate insulation film 502. The second electrode 552 may be connected to the second auxiliary electrode AUX2 exposed through the opening (etch hole) of the gate insulation film 502. Accordingly, the second electrode 552 may be electrically connected to the second area 522 of the first active layer 520 through the second auxiliary electrode AUX2.

Referring to FIG. 5, in the display panel 110 of the display device 100 according to aspects of the disclosure, the light shield 510 may be positioned between the substrate 500 and the buffer layer 501 and may overlap with the channel area 525 of the first active layer 520.

The light shield 510 may include a single layer or more layers. The light shield 510 may include copper(Cu), aluminum (Al), molybdenum (Mo), titanium (Ti), molydenumtitanium (MoTi) or the like.

Referring to FIG. 5, when the light shield 510 include two layers, the light shield 510 may include a lower light shield 510a and an upper light shield 510b on the lower light shield 510a.

The lower light shield 510a may include the first metal (e.g., MoTi, but not limited thereto) included in the first lower electrode 551a, the second lower electrode 552a, and/or the third lower electrode 553a. The upper light shield 510b may include the second metal (e.g., Cu, but not limited thereto) included in the first upper electrode 551b, the second upper electrode 552b. For example, the first metal may include molybdenum (Mo), titanium (Ti), or molydenum titanium (MoTi). The second metal may include copper (Cu), aluminum (Al), or the like. But aspects of the present disclosure are not limited thereto.

Alternatively, when the light shield 510 include n (where n is an integer greater than 2) layers, the light shield 510 may include a lower light shield 510a, one or more middle light shields (not shown) on the lower light shield 510a, and an upper light shield 510b on the one or more middle light shields.

The lower light shield 510a may include the first metal (e.g., MoTi, but not limited thereto) included in the first lower electrode 551a, the second lower electrode 552a, and/or the third lower electrode 553a. The upper light shield 510b may include the second metal (e.g., Cu, but not limited thereto) included in the first upper electrode 551b, the second upper electrode 552b. The one or more middle light shields may include the first metal and/or the second metal. For example, the first metal may include molybdenum (Mo), titanium (Ti), or molydenumtitanium (MoTi). The second metal may include copper (Cu), aluminum (Al), or the like. But aspects of the present disclosure are not limited thereto.

Referring to FIG. 5, the lower light shield 510a and the upper light shield 510b included in the light shield 510 may or may not be electrically connected to each other.

Referring to FIG. 5, the first lower electrode 551a or the second lower electrode 552a may be connected to the upper light shield 510b through the through hole of the buffer layer 501 and the gate insulation film 502. Accordingly, the light shield 510 may be electrically connected to the first node N1 of the driving transistor DRT (see FIG. 4).

Referring to FIG. 6, an insulation film 603 may be disposed on the substrate 500 on which the first electrode 551, the second electrode 552, and the third electrode 553 are disposed.

The insulation film 603 may include various insulation film materials such as silicon nitride (SiNₓ) and silicon dioxide (SiOₓ).

Referring to FIG. 6, a pixel electrode 670 may be disposed on the insulation film 603 without the light shield 510 in the structure as shown in FIG. 5.

The pixel electrode 670 may contact the second electrode 552 (e.g., the second upper electrode 552b) of the transistor Tr through a contact hole provided in the insulation film 603. FIG. 6 illustrates a structure in which the pixel electrode 670 contacts the second electrode 552, but aspects of the disclosure are not limited thereto, and the pixel electrode 670 may contact the first electrode 551 (e.g., the first upper electrode 551b) through a contact hole of the insulation film 603 exposing a portion of the surface of the first electrode 551.

FIGS. 5 and 6 illustrate a structure in which the third electrode 553 is disposed on the first active layer 520 (i.e., top gate structure), but aspects of the disclosure are not limited thereto, and the third electrode 553 may be disposed under the first active layer 520 (i.e., bottom gate structure).

The transistor having the structure shown in FIGS. 5 and 6 may be used as a structure of at least one transistor included in the display panel.

For example, the transistor disposed on the display panel 110 according to aspects of the disclosure may be at least one of transistors DRT, SCT, and SENT disposed for each subpixel SP in the display area DA.

Further, the transistors disposed on the display panel 110 according to aspects of the disclosure may be transistors included in the GIP-type gate driving circuit 130 formed in the non-display area NDA.

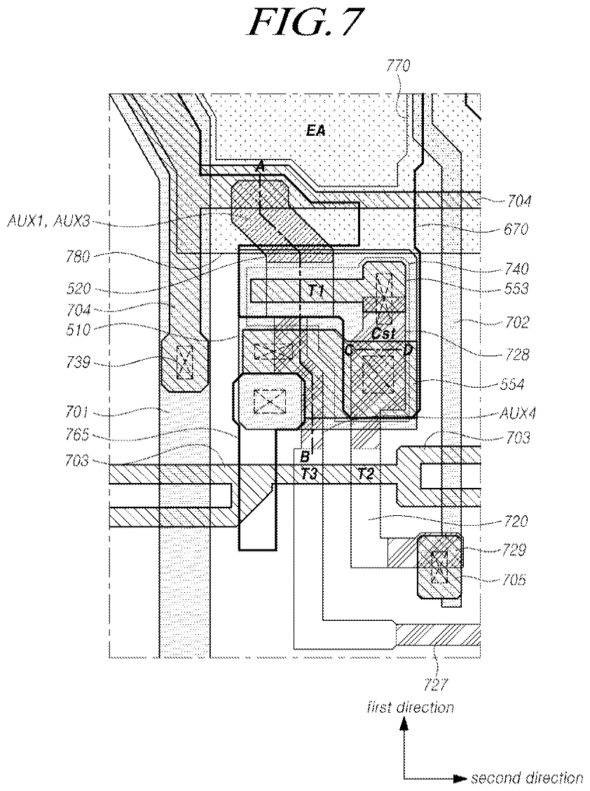

FIG. 7 is a view illustrating a portion of an active area in a display panel according to aspects of the disclosure.

In the following description, contents (configurations, effects, etc.) overlapping with the above-described aspects may be omitted or may be briefly provided. Further, in the following description, the same reference numerals may be used to denote the components same or similar as the above-described aspects.

Referring to FIG. 7, at least one subpixel of the display panel according to aspects of the disclosure may include a light-emitting area EA and a non-light-emitting area divided by the bank 770.

In the active area of the display panel, the light-emitting area EA may be an area that does not overlap with the bank 770, and the non-light-emitting area may be an area that overlaps with the bank 770.

An organic light-emitting device OLED including an anode electrode, an organic layer, and a cathode electrode may be disposed in the light-emitting area EA. A color filter 780 may be disposed on the organic light-emitting device OLED, but the disclosure is not limited thereto. For example, the color filter 780 may be disposed in only some subpixels among the plurality of subpixels included in the display device 100, or the color filter 780 may not be disposed in all the subpixels included in the display device 100.

As illustrated in FIG. 7, the color filter 780 may be disposed to overlap with the entire light-emitting area EA and a portion of the non-light-emitting area.

At least one transistor may be disposed in one subpixel. For example, as illustrated in FIG. 7, a first transistor T1, a second transistor T2, and a third transistor T3 may be disposed in one subpixel.

At least one of the first transistor T1, the second transistor T2, and the third transistor T3 may have the structure of FIG. 5 or 6, but aspects of the present disclosure are not limited thereto.

A first signal line 701 and a second signal line 702 that are disposed on the same layer as the light shield 510 and extend in a first direction may be disposed on the substrate. Here, the first signal line 701 may be the driving voltage line DVL of FIG. 2, FIG. 3, and FIG. 4, and the second signal line 702 may be a data line (DL of FIGS. 2 to 4), but aspects of the disclosure are not limited thereto. For example, each of the first and second signal lines 701 and 702 may be a data line.

However, for convenience of description, the following description focuses primarily on a structure in which the first signal line 701 is a driving voltage line and the second signal line 702 is a data line.

A first active layer 520 may be disposed on the light shield 510.

Here, a portion of the first active layer 520 may overlap with a portion of the light shield 510.

FIG. 7 illustrates a structure in which the light shield 510 is disposed under the first active layer 520, but in some cases, as illustrated in FIG. 6, the light shield 510 may not be disposed under the first active layer 520.

Further, a second active layer 720 that is disposed on the same layer as the first active layer 520 and is spaced apart from the first active layer 520 may be disposed on the substrate 500.

Referring to FIG. 7, the first auxiliary electrode AUX1 may be disposed on the substrate on which the first and second active layers 520 and 720 are disposed. As illustrated in FIGS. 5 and 6, a third auxiliary electrode AUX3 may be disposed under the first auxiliary electrode AUX1.

Further, a first additional auxiliary electrode 727, a second additional auxiliary electrode 728, and a third additional auxiliary electrode 729 (not shown) spaced apart from each other may be disposed on the same layer as the third auxiliary electrode AUX3.

Referring to FIG. 7, the first additional auxiliary electrode 727 may be disposed on the first active layer 520, and the second and third additional auxiliary electrodes 728 and 729 may be disposed on the second active layer 720.

A third electrode 553, a third signal line 703, a fourth signal line 704, and a fourth electrode 705 may be disposed on the substrate on which the first auxiliary electrode AUX1, the third auxiliary electrode AUX3, and the first to third additional auxiliary electrodes 727, 728, and 729 are disposed.

The third electrode 553 may be the gate electrode of the first transistor T1 and may be integrally formed with the plate 554.

The third signal line 703 may be a gate line.

The third signal line 703 may connect to the gate electrode of the second transistor T2 and the gate electrode of the third transistor T3.

The fourth signal line 704 may be disposed to overlap with a portion of the first signal line 701. The fourth signal line 704 and the first signal line 701 may be electrically connected through contact holes of a plurality of insulation films disposed under the fourth signal line 704. Accordingly, the resistance of the signal line may be reduced.

Further, the fourth signal line 704 may include an extension extending in a direction crossing the direction in which the first signal line 701 extends. The plurality of subpixels may be supplied with a driving voltage through the extension of the fourth signal line 704, but aspects of the disclosure are not limited thereto. For example, when the first signal line 701 is a data line, the fourth signal line 704 may not be disposed on the first signal line 701.

Referring to FIG. 7, the first transistor T1 may include a first active layer 520, a first auxiliary electrode AUX1 (including a third auxiliary electrode AUX3 disposed under the first auxiliary electrode AUX1), a fourth auxiliary electrode AUX4, a third electrode 553, a fourth signal line 704, and a plate 554. Here, each of the fourth signal line 704 and the plate 554 may serve as either the source electrode or the drain electrode of the first transistor T1.

Referring to FIG. 7, specifically, in the first transistor T1, the auxiliary electrode on the first active layer 520 may include a first auxiliary electrode AUX1 disposed on a portion of the upper surface of the first active layer 520, a third auxiliary electrode AUX3 disposed under the first auxiliary electrode AUX1, and a fourth auxiliary electrode AUX4 disposed on a portion of the upper surface of the first active layer 520 and spaced apart from the third auxiliary electrode AUX3.

Here, the area in which the first auxiliary electrode AUX1 and the third auxiliary electrode AUX3 are disposed may be a repair area of the subpixel.

When there is a defective subpixel among the subpixels of the display panel, the subpixel may be required to be repaired to block the signal supplied from the driving transistor to the organic light-emitting device disposed in the corresponding subpixel.

For example, when a defect occurs in the subpixel, the first active layer 520 may be cut by, e.g., a laser.

Meanwhile, as the first active layer 520 is formed of a transparent oxide semiconductor, the first active layer 520 may not be visible in the cutting process using a laser. Accordingly, as illustrated in FIG. 7, as the first auxiliary electrode AUX1 is disposed on the first active layer 520 and the first auxiliary electrode AUX1 includes metal, the position of the first active layer 520 may be determined through the first auxiliary electrode AUX1 during laser cutting.

In other words, since the first auxiliary electrode AUX1 is opaque, the position of the repair may be easily identified through the first auxiliary electrode AUX1. Alternatively, the third auxiliary electrode AUX3 is disposed under the first auxiliary electrode AUX1, the position of the first active layer 520 may be determined through the third auxiliary electrode AUX3 during laser cutting.

In particular, the thickness of the first auxiliary electrode AUX1 may be 100 Å to 200 Å, and when the thickness of the first auxiliary electrode AUX1 is less than 100 Å, the transmission characteristic of light may be enhanced, and it may be difficult to identify the position of repair.

The second transistor T2 may include a second active layer 720, a second additional auxiliary electrode 728, a third additional auxiliary electrode 729, a third signal line 703, a plate 554, and a fourth electrode 705. Here, each of the plate 554 and the fourth electrode 705 may serve as either the source electrode or the drain electrode of the second transistor T2.

The third transistor T3 may include a first active layer 520, a fourth auxiliary electrode AUX4, a first additional auxiliary electrode 727, a third signal line 703, and a plate 554. Here, the plate 554 may serve as either the source electrode or the drain electrode of the third transistor T3 (the remaining electrode is not shown).

The first transistor T1 may be a driving transistor, and a storage capacitor Cst may be disposed in one subpixel.

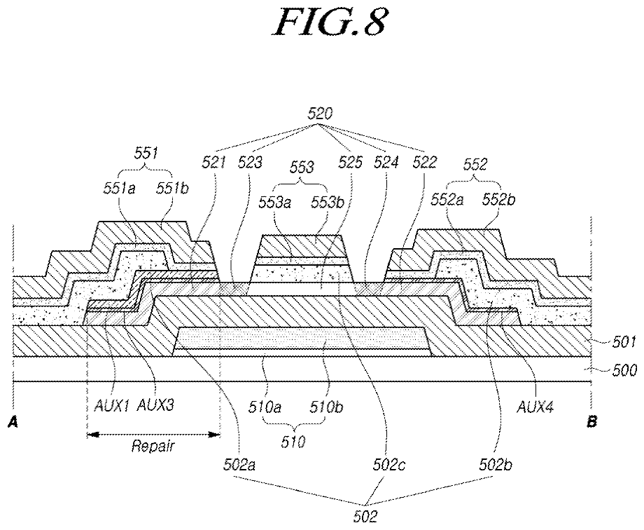

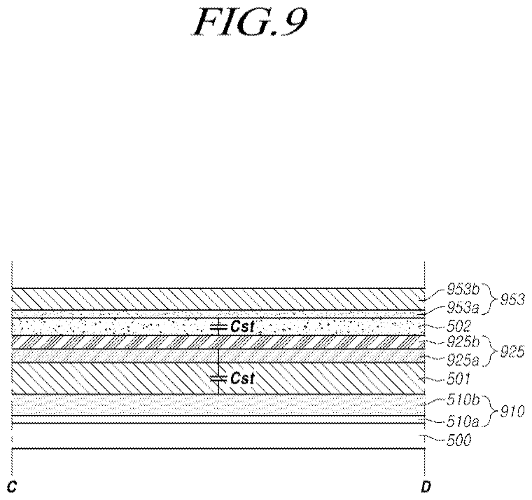

The structure of the first transistor T1 and the storage capacitor Cst is described below with reference to FIGS. 8 and 9.

FIG. 8 is a cross-sectional view taken along line A-B of FIG. 7, and FIG. 9 is a cross-sectional view taken along line C-D of FIG. 7.

In the following description, contents (configurations, effects, etc.) overlapping with the above-described aspects may be omitted or may be briefly provided. Further, in the following description, the same reference numerals may be used to denote the components same or similar as the above-described aspects.

Referring to FIG. 8, a first transistor T1 according to exemplary aspects of the disclosure may include a first active layer 520, a first auxiliary electrode AUX1, a third auxiliary electrode AUX3, a fourth auxiliary electrode AUX4, a first electrode 551, a second electrode 552, and a third electrode 553. Differently from the exemplary aspect as shown in FIG. 6, no auxiliary electrode is disposed on the fourth auxiliary electrode AUX4.

A light shield 510 may be disposed under the first active layer 520.

Referring to FIG. 8, a third auxiliary electrode AUX3 and a fourth auxiliary electrode AUX4 spaced apart from each other may be disposed on the first active layer 520 of the first transistor T1. The first auxiliary electrode AUX1 may be disposed on the third auxiliary electrode AUX3.

An area in which the first auxiliary electrode AUX1 is disposed in at least one subpixel may correspond to a repair area. As the first auxiliary electrode AUX1 including the metallic material is disposed in the repair area, the position of the first active layer 520 may be identified through the position of the first auxiliary electrode AUX1 during the repair process, and thus the first active layer 520 may be easily cut.

The first electrode 551 may be disposed on the first auxiliary electrode AUX1, and the second electrode 552 may be disposed on the fourth auxiliary electrode AUX4.

Referring to FIG. 8, a gate insulation film 502 may be disposed on the first active layer 520, and a third electrode 553 may be disposed on the gate insulation film. Here, the first electrode 551, the second electrode 552, and the third electrode 553 may be disposed on the same layer and may include the same material. But aspects of the present disclosure are not limited thereto, the first electrode 551, the second electrode 552, and the third electrode 553 may also be disposed on different layers and may also include different materials.

Referring to FIG. 9, a subpixel according to aspects of the disclosure may include at least one storage capacitor Cst.

The storage capacitor Cst may include a plurality of capacitor electrodes. For example, as illustrated in FIG. 9, a first capacitor electrode 910, a second capacitor electrode 925, and a third capacitor electrode 953 may be included.

A buffer layer 501 may be disposed between the first capacitor electrode 910 and the second capacitor electrode 925.

A gate insulation film 502 may be disposed between the second capacitor electrode 925 and the third capacitor electrode 953.

In FIG. 9, the first capacitor electrode 910 of the storage capacitor Cst may be an electrode where the light shield 510 extends, an electrode electrically connected to the light shield 510, or an electrode including the same metal as the metal included in the light shield 510.

When the light shield 510 includes the lower light shield 510a and the upper light shield 510b, the first capacitor electrode 910 may include the first lower capacitor electrode 910a and the first upper capacitor electrode 910b (not shown).

The first lower capacitor electrode 910a may be an electrode where the lower light shield 510a extends, an electrode electrically connected to the lower light shield 510a, or an electrode including the same metal as the metal included in the lower light shield 510a.

The first upper capacitor electrode 910b may be an electrode where the upper light shield 510b extends, an electrode electrically connected to the upper light shield 510b, or an electrode including the same metal as the metal included in the upper light shield 510b.

Referring to FIG. 9, the second capacitor electrode 925 of the storage capacitor Cst may be configured as a single layer including the same semiconductor material as the semiconductor material included in the second active layer 720. In this case, the second capacitor electrode 925 may be an electrode in which the same semiconductor material as that of the second active layer 720 has been rendered conductive.

When the second additional auxiliary electrode 728 is further disposed on the second active layer 720, the second capacitor electrode 925 may include a second lower capacitor electrode 925a and a second upper capacitor electrode 925b.

The second lower capacitor electrode 925a may include a semiconductor material of the second active layer 720. Here, the second lower capacitor electrode 925a may be a non-conductive semiconductor material or a conductive semiconductor material.

The second upper capacitor electrode 925b may include the same material as the second additional auxiliary electrode 728. For example, the second upper capacitor electrode 925b may include a conductive oxide (e.g., indium tin oxide (ITO) or indium zinc oxide (IZO) or the like). But aspects of the present disclosure are not limited thereto.

Referring to FIG. 9, the third capacitor electrode 953 of the storage capacitor Cst may be an electrode where the first electrode 551, the second electrode 552, or the third electrode 553 extends, an electrode electrically connected to the first electrode 551, the second electrode 552, or the third electrode 553, or an electrode including the same metal as the first electrode 551, the second electrode 552, or the third electrode 553.

When the third electrode 553 includes the third lower electrode 553a and the third upper electrode 553b, the third capacitor electrode 953 may include the third lower capacitor electrode 953a and the third upper capacitor electrode 953b.

The third lower capacitor electrode 953a may include the metal included in the lower electrode 551a, 552a, or 553a of the first electrode 551, the second electrode 552, or the third electrode 553.

The third upper capacitor electrode 953b may include the metal included in the upper electrode 551b, 552b, or 553b of the first electrode 551, the second electrode 552, or the third electrode 553. But aspects of the present disclosure are not limited thereto.

The storage capacitor Cst may be connected between the source node and the gate node of the driving transistor DRT. For example, in the driving transistor DRT, the source node may be the first electrode 551 or the second electrode 552, and the gate node may be the third electrode 553. The first electrode 551 or the second electrode 552 which is the source node of the driving transistor DRT may be electrically connected to the light shield 510.

For example, the third capacitor electrode 953 may be electrically connected to the first electrode 551 or the second electrode 552 which is the source node of the driving transistor DRT. The second capacitor electrode 925 may be electrically connected to the third electrode 553 which is the gate node of the driving transistor DRT. The first capacitor electrode 910 may be electrically connected to the first electrode 551 or the second electrode 552 which is the source node of the driving transistor DRT. Accordingly, the storage capacitor Cst may have the structure in which two capacitors are connected in parallel, and thus the value of the storage capacitor Cst may increase.

The two capacitors connected in parallel to constitute the storage capacitor Cst may include a first capacitor formed between the second capacitor electrode 925 and the third capacitor electrode 953 and a second capacitor formed between the second capacitor electrode 925 and the first capacitor electrode 910.

FIG. 7 illustrates a structure in which an auxiliary electrode including a metal is disposed to correspond to a repair area in at least one sub pixel, but aspects of the disclosure are not limited thereto.

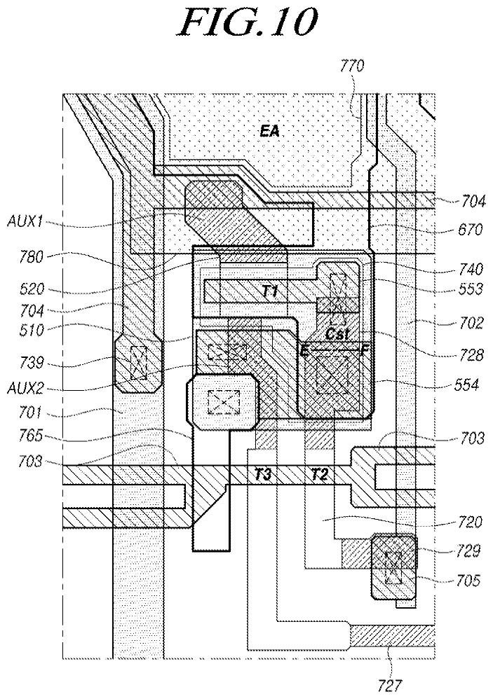

A subpixel structure of a display panel according to aspects of the disclosure is described with reference to FIG. 10.

FIG. 10 is a plan view illustrating a pad area of an active area in a display panel according to aspects of the disclosure.

In the following description, contents (configurations, effects, etc.) overlapping with the above-described aspects may be omitted or may be briefly provided. Further, in the following description, the same reference numerals may be used to denote the components same or similar as the above-described aspects.

In addition to the structure of FIG. 7, FIG. 10 may further include a second auxiliary electrode AUX2 disposed on the first active layer 520 (including a fourth auxiliary electrode AUX4 disposed under the second auxiliary electrode AUX2) and a first additional auxiliary electrode 727, and a second additional auxiliary electrode 728 and a third additional auxiliary electrode 729 disposed on the second active layer 720.

Referring to FIG. 10, the first to fourth auxiliary electrodes AUX1, AUX2, AUX3, and AUX4 may be disposed on the substrate on which the first and second active layers 520 and 720 are disposed. As illustrated in FIGS. 5 and 6, the third auxiliary electrode AUX3 may be disposed under the first auxiliary electrode AUX1, and the fourth auxiliary electrode AUX4 may be disposed under the second auxiliary electrode AUX2.

As illustrated in FIG. 10, not only the first to fourth auxiliary electrodes AUX1, AUX2, AUX3, and AUX4, but also the first additional auxiliary electrode 727 spaced apart from the first to fourth auxiliary electrodes AUX1, AUX2, AUX3, and AUX4 and disposed on the same layer as the first to fourth auxiliary electrodes AUX1, AUX2, AUX3, and AUX4 may be disposed on the first active layer 520.

Referring to FIG. 10, a second additional auxiliary electrode 728 and a third additional auxiliary electrode 729 disposed on the same layer as the first additional auxiliary electrode 727 may be included on the second active layer 720. The second additional auxiliary electrode 728 and the third additional auxiliary electrode 729 may be spaced apart from each other.

Each of the first to third additional auxiliary electrodes 727, 728, and 729 may have a structure in which at least two layers are stacked. For example, each of the first to third additional auxiliary electrodes 727, 728, and 729 may be a structure in which two or more layers are stacked to correspond to a structure in which the first auxiliary electrode AUX1 and the third auxiliary electrode AUX3 disposed on the first active layer 520 are stacked or a structure in which the second auxiliary electrode AUX2 and the fourth auxiliary electrode AUX4 disposed on the first active layer 520 are stacked in FIGS. 5 and 6.

In this case, the lower layer of each of the first to third additional auxiliary electrodes 727, 728, and 729 may include a conductive oxide including oxygen. For example, the conductive oxide may include at least one of a transparent conductive oxide, a nitric oxide, and an organic material. The upper layer of each of the first to third additional auxiliary electrodes 727, 728, and 729 may include metal. But aspects of the present disclosure are not limited thereto.

The third electrode 553, the third signal line 703, the fourth signal line 704, and the fourth electrode 705 may be disposed on the substrate on which the first to fourth auxiliary electrodes AUX1, AUX2, AUX3, and AUX4 and the first to third additional auxiliary electrodes 727, 728, and 729 are disposed.

The third electrode 553 may be the gate electrode of the first transistor T1 and may be integrally formed with the plate 554.

The third signal line 703 may be a gate line.

At least part of the third signal line 703 may be the gate electrode of the second transistor T2 and the gate electrode of the third transistor T3.

The fourth signal line 704 may be disposed to overlap with a portion of the first signal line 701. The fourth signal line 704 and the first signal line 701 may be electrically connected through contact holes of a plurality of insulation films disposed under the fourth signal line 704. Accordingly, the resistance of the signal line may be reduced.

Further, the fourth signal line 704 may include an extension extending in a direction crossing the direction in which the first signal line 701 extends. The plurality of subpixels may be supplied with a driving voltage through the extension of the fourth signal line 704, but aspects of the disclosure are not limited thereto. For example, when the first signal line 701 is a data line, the fourth signal line 704 may not be disposed on the first signal line 701.

Referring to FIG. 10, the first transistor T1 may include a first active layer 520, a first auxiliary electrode AUX1 (including a third auxiliary electrode AUX3 disposed under the first auxiliary electrode AUX1), a second auxiliary electrode AUX2 (including a fourth auxiliary electrode AUX4 disposed under the second auxiliary electrode AUX2), a third electrode 553, a fourth signal line 704, and a plate 554. Here, each of the fourth signal line 704 and the plate 554 may serve as either the source electrode or the drain electrode of the first transistor T1.

The second transistor T2 may include a second active layer 720, a second additional auxiliary electrode 728, a third additional auxiliary electrode 729, a third signal line 703, a plate 554, and a fourth electrode 705. Here, each of the plate 554 and the fourth electrode 705 may serve as either the source electrode or the drain electrode of the second transistor T2.

The third transistor T3 may include a first active layer 520, a second auxiliary electrode AUX2, a first additional auxiliary electrode 727, a third signal line 703, and a plate 554. Here, the plate 554 may serve as either the source electrode or the drain electrode of the third transistor T3.

The cross-sectional structure of the first to third transistors T1, T2, T3 may correspond to the transistor structure of FIG. 5 or 6.

Also, the storage capacitor Cst disposed in the subpixel illustrated in FIG. 10 may be different from the structure of FIG. 9.

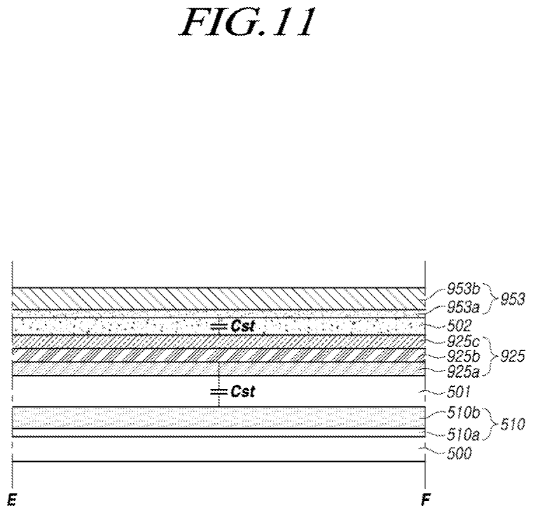

This is discussed below with reference to FIG. 11.

FIG. 11 is a cross-sectional view taken along line E-F of FIG. 10.

In the following description, contents (configurations, effects, etc.) overlapping with the above-described aspects may be omitted or may be briefly provided. Further, in the following description, the same reference numerals may be used to denote the components same or similar as the above-described aspects.

The storage capacitor Cst of FIG. 11 may include a plurality of capacitor electrodes. For example, as illustrated in FIG. 11, a first capacitor electrode 910 (at the position of light shield 510, not shown), a second capacitor electrode 925, and a third capacitor electrode 953 may be included.

The first capacitor electrode 910 and the third capacitor electrode 953 of the storage capacitor Cst of FIG. 11 may be the same or basically the same as the first capacitor electrode 910 and the third capacitor electrode 953 of the storage capacitor Cst of FIG. 9.

The second capacitor electrode 925 of the storage capacitor Cst of FIG. 11 may include a second lower capacitor electrode 925a, a second upper capacitor electrode 925b, and an additional capacitor electrode 925c.

Referring to FIG. 11, the additional capacitor electrode 925c may be an electrode where the uppermost layer of the second additional auxiliary electrode 728 extends. The additional capacitor electrode 925c may include a metal, for example, the additional capacitor electrode 925c may include a metal that is different from that of the second lower capacitor electrode 925a and the second upper capacitor electrode 925b, but aspects of the disclosure are not limited thereto, the additional capacitor electrode 925c may also include a metal that is same to that of at least one of the second lower capacitor electrode 925a and the second upper capacitor electrode 925b.

Aspects of the disclosure may provide a display panel comprising a first active layer disposed on a substrate and including a channel area, a first area positioned on a first side of the channel area, and a second area positioned on a second side of the channel area, a first conductor on the first area, a second conductor on the second area, and a first auxiliary electrode on the first conductor, wherein an area where the first auxiliary electrode is disposed includes a repair area, thereby facilitating to repair a subpixel while mitigating or minimizing instantaneous ghosting on panel.

Aspects of the disclosure may provide a display device comprising a first active layer disposed on a substrate and including a channel area, a first area positioned on a first side of the channel area, and a second area positioned on a second side of the channel area, a first conductor disposed on the first area, a second conductor disposed on the second area, a first auxiliary electrode disposed on the first conductor, a first electrode on the first auxiliary electrode, a second electrode on the second conductor, and a third electrode overlapping with the channel area, wherein an area where the first auxiliary electrode is disposed includes a repair area.

According to aspects of the disclosure, there may be provided a display panel and a display device capable of preventing or minimizing instantaneous ghosting on panel by including auxiliary electrodes in a pad area on the active layer.

According to aspects of the disclosure, there may be provided a display panel and a display device capable of preventing or minimizing instantaneous ghosting on panel while facilitating a subpixel repair process through cutting the active layer by including a plurality of auxiliary electrodes disposed on the active layer.

The above description has been presented to enable any person skilled in the art to make and use the technical idea of the disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the disclosure. The above description and the accompanying drawings provide an example of the technical idea of the disclosure for illustrative purposes only. That is, the disclosed aspects are intended to illustrate the scope of the technical idea of the disclosure. Thus, the scope of the disclosure is not limited to the aspects shown, but is to be accorded the widest scope consistent with the claims. The scope of protection of the disclosure should be construed based on the following claims, and all technical ideas within the scope of equivalents thereof should be construed as being included within the scope of the disclosure.

What is claimed is:

1. A display panel, comprising:
a substrate;
a first active layer disposed on the substrate and including a channel area, a first area positioned on a first side of the channel area, and a second area positioned on a second side of the channel area;
a first conductor disposed on the first area;
a second conductor disposed on the second area; and
a first auxiliary electrode disposed on the first conductor,
a repair area disposed in an area where the first auxiliary electrode is located.

2. The display panel of claim 1, further comprising a second active layer disposed on a same layer as the first active layer and spaced apart from the first active layer.

3. The display panel of claim 1, further comprising:
a first additional auxiliary electrode disposed on the first active layer; and
a second additional auxiliary electrode and a third additional auxiliary electrode spaced apart from each other and disposed on the second active layer.

4. The display panel of claim 1, further comprising a second auxiliary electrode disposed on the second conductor.

5. The display panel of claim 4, wherein each of the first auxiliary electrode and the second auxiliary electrode includes one type of metal or an alloy in which two or more types of metal components are mixed, and
wherein each of the first conductor and the second conductor includes a transparent conductive oxide.

6. The display panel of claim 5, wherein each of the first and second auxiliary electrodes is formed of MoTi, and each of the first and second conductors is formed of indium zinc oxide (IZO).

7. The display panel of claim 6, wherein a content ratio of indium (In) to zinc (Zn) included in each of the first and second conductors is 5:5 to 7:3.

8. The display panel of claim 5, wherein thicknesses of each of the first and second auxiliary electrodes are larger than or equal to thicknesses of each of the first and second conductors.

9. The display panel of claim 8, wherein each of the first and second auxiliary electrodes has a thickness of 100 Å to 200 Å, and
wherein each of the first and second conductors has a thickness of 70 Å to 100 Å.

10. The display panel of claim 5, wherein the first area overlapping with the first auxiliary electrode is cut during a repair process of the display panel.

11. The display panel of claim 4, further comprising:
a first electrode disposed on the first auxiliary electrode;
a second electrode disposed on the second auxiliary electrode;
a gate insulation film disposed on the channel area; and
a third electrode disposed on the gate insulation film.

12. The display panel of claim 11, wherein the gate insulation film includes:
a first gate insulation film portion disposed to cover a first end positioned farther from the channel area, of the first end and a second end of the first auxiliary electrode;
a second gate insulation film portion disposed to cover a second end positioned farther from the channel area, of a first end and the second end of the second auxiliary electrode; and
a third gate insulation film portion positioned on the channel area,
wherein the first electrode is positioned on an upper surface and a side surface of the first gate insulation film portion and contacts a portion of an upper surface of the first auxiliary electrode on the side surface of the first gate insulation film portion,
wherein the second electrode is positioned on an upper surface and a side surface of the second gate insulation film portion and contacts a portion of an upper surface of the second auxiliary electrode on the side surface of the second gate insulation film portion, and
wherein the third electrode is positioned on an upper surface of the third gate insulation film portion.

13. The display panel of claim 11, wherein the first electrode includes a first lower electrode and a first upper electrode electrically connected to each other,
wherein the second electrode includes a second lower electrode and a second upper electrode electrically connected to each other,
wherein the third electrode includes a third lower electrode and a third upper electrode electrically connected to each other,
wherein the first lower electrode, the second lower electrode, and the third lower electrode commonly include a first metal, and
wherein the first upper electrode, the second upper electrode, and the third upper electrode commonly include a second metal different from the first metal.

14. The display panel of claim 11, wherein the first electrode includes a first lower electrode and a first upper electrode electrically connected to each other,
wherein the second electrode includes a second lower electrode, a second additional capacitor electrode, and a second upper electrode electrically connected to each other,
wherein the third electrode includes a third lower electrode and a third upper electrode electrically connected to each other,
wherein the first lower electrode, the second lower electrode, and the third lower electrode commonly include a first metal,
wherein the first upper electrode, the second upper electrode, and the third upper electrode commonly include a second metal different from the first metal, and
wherein the second additional capacitor electrode includes a third metal different from the first metal and the second metal.

15. The display panel of claim 11, further comprising a light shield disposed between the substrate and a buffer layer and overlapping with the channel area,
wherein the light shield includes a lower light shield and an upper light shield on the lower light shield,
wherein the lower light shield includes the first metal included in the first lower electrode, the second lower electrode, or the third lower electrode, and
wherein the upper light shield includes the second metal included in the first upper electrode, the second upper electrode, or the third upper electrode.

16. The display panel of claim 15, wherein the first lower electrode or the second lower electrode is connected to the upper light shield through a through hole of the buffer layer and the gate insulation film.

17. The display panel of claim 13, further comprising:
a driving transistor disposed in a display area and including the first active layer, the first conductor, the second conductor, the first auxiliary electrode, the first electrode, the second electrode, and the third electrode;
a storage capacitor connected between the first electrode and the third electrode of the driving transistor; and
a light shield disposed between the substrate and a buffer layer and overlapping with the channel area,
wherein the storage capacitor includes a first capacitor electrode, a second capacitor electrode positioned on the first capacitor electrode, and a third capacitor electrode positioned on the second capacitor electrode, and
wherein the buffer layer is positioned between the first capacitor electrode and the second capacitor electrode, and
wherein the gate insulation film is positioned between the second capacitor electrode and the third capacitor electrode.

18. The display panel of claim 17, wherein the first capacitor electrode includes a metal included in the light shield,
wherein the second capacitor electrode includes a semiconductor material film and a conductive oxide film on the semiconductor material film,
wherein the semiconductor material film includes an oxide semiconductor included in the active layer,
wherein the conductive oxide film includes a conductive material included in the first conductor and the second conductor, and
wherein the third capacitor electrode includes a metal included in the third electrode.

19. The display panel of claim 18, wherein the second capacitor electrode further includes an additional metal film disposed on the metal film, and
wherein the additional metal film includes a metal included in the first auxiliary electrode.

20. The display panel of claim 18, further comprising a second active layer spaced apart from the first active layer,
wherein the second active layer is included in the second capacitor electrode.

21. The display panel of claim 1, wherein the first active layer further includes a third area disposed between the first area and the channel area and a fourth area disposed between the second area and the channel area, and
wherein the first area and the second area are non-conductive areas, and the third area and the fourth area are conductive areas.

22. A display device comprising the display panel of claim 1.

23. A display device, comprising:
a substrate;
a first active layer disposed on the substrate and including a channel area, a first area positioned on a first side of the channel area, and a second area positioned on a second side of the channel area;
a first conductor disposed on the first area and including a transparent conductive oxide;
a second conductor disposed on the second area and including a transparent conductive oxide;
a first auxiliary electrode disposed on the first conductor and formed of one type of metal or an alloy in which two or more types of metal components are mixed;
a first electrode on the first auxiliary electrode;
a second electrode on the second conductor; and
a third electrode overlapping with the channel area,
a repair area disposed in an area where the first auxiliary electrode is located.

24. The display device of claim 23, wherein the first area overlapping with the first auxiliary electrode is cut during a repair process.
